(19) United States
(12) Patent Application Publication
(10) Pub. No.: US 2025/0248072 A1
(43) Pub. Date: Jul. 31, 2025

(54) SEMICONDUCTOR STRUCTURE

(71) Applicant: TAIWAN SEMICONDUCTOR MANUFACTURING COMPANY, LTD., Hsinchu (TW)

(72) Inventors: I-Che LEE, Hsinchu (TW); Wei-Gang CHIU, Hsinchu (TW); Huai-Ying HUANG, Hsinchu (TW); Yen-Chieh HUANG, Hsinchu (TW); Kai-Wen CHENG, Hsinchu (TW); Yu-Ming LIN, Hsinchu (TW)

(73) Assignee: TAIWAN SEMICONDUCTOR MANUFACTURING COMPANY, LTD., Hsinchu (TW)

(21) Appl. No.: 18/425,352

(22) Filed: Jan. 29, 2024

(51) Int. Cl. H01L 29/786; H01L 23/522; H01L 23/528; H01L 27/06; H01L 29/66

(52) U.S. Cl. CPC H10D 30/6757; H01L 23/5223; H01L 23/5283; H10D 30/026; H10D 84/811

(57) ABSTRACT

A semiconductor structure includes a base structure having a conductive feature therein, a transistor disposed above the base structure, a capacitor disposed on the transistor, and an interconnecting routing that interconnects the second electrode with the conductive feature. The transistor includes a gate electrode, a gate dielectric, a channel spaced apart from the gate electrode through the gate dielectric, and two contact structures connected to the channel and spaced apart from each other. Each of the two contact structures includes a main body, and a protection layer that includes a transition metal which is one of elements of groups 3 to 12 in periods 5 to 7, elements of lanthanide series, and elements of actinide series. The capacitor includes a first electrode connected to one of the two contact structures of the transistor, a second electrode, and a dielectric interposed between the first electrode and the second electrode.

### BACKGROUND

Transistors are fabricated in back-end-of-line (BEOL) of semiconductor devices for computing or selection of memory. In order to enhance performance and reliability of the transistors, structures and materials of the transistors, and process flow for preparing the same are continuously improved with advancement of technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view illustrating a semiconductor structure including a transistor in accordance with some embodiments.

FIG. 2 is an enlarged view of a region outlined by a dotted line (X) shown in FIG. 1 illustrating a transistor and a corresponding capacitor in accordance with some embodiments.

FIGS. 3 to 7 are different variations of the structure shown in FIG. 2 in accordance with some embodiments.

FIG. 8 is a flow diagram illustrating a method for manufacturing the structure shown in FIG. 2 in accordance with some embodiments.

FIGS. 9 to 15 are schematic views illustrating different variations of the transistor in accordance with some embodiments.

FIG. 16 is a schematic view illustrating another semiconductor structure including another variation of the transistor in accordance with some embodiments.

FIGS. 17 to 23 are schematic views illustrating different variations of the transistor in accordance with some embodiments.

FIG. 24 is a flow diagram illustrating a method for manufacturing the structure shown in FIG. 17 in accordance with some embodiments.

FIG. 25 is a schematic view illustrating a structure simulating a top-gate transistor in accordance with some embodiments.

FIG. 26 is a diagram showing distribution of hydrogen concentration in three samples of the structure shown in FIG. 25 in accordance with some embodiments, in which two of the samples are each formed with a thin protection layer.

FIG. 27 is a diagram showing distribution of hydrogen concentration in three samples of the structure shown in FIG. 25 in accordance with some embodiments, in which two of the samples are each formed with a thick protection layer.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a back-end transistor, and a semiconductor structure including the same. In some embodiments, the semiconductor structure may further include a capacitor, and may be applied in back-end-of-line (BEOL), such as an embedded-transistor-capacitor application, a dynamic random-access memory (DRAM), an electrostatic discharge device (ESD), a radio frequency (RF) device, but are not limited thereto.

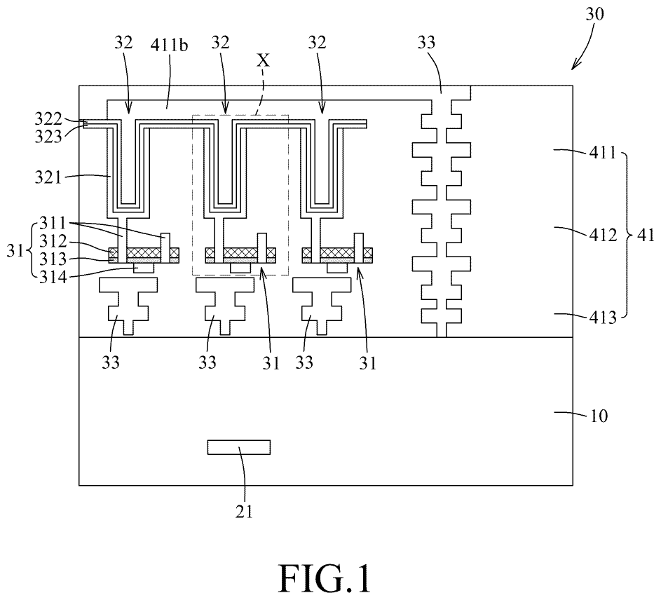

FIG. 1 is a schematic view of a semiconductor structure in accordance with some embodiments of the present disclosure.

The semiconductor structure includes a base structure 10, and a back-end-of-line (BEOL) section 30.

The base structure 10 may include a substrate (not shown), and a conductive feature 21.

In some embodiments, the substrate may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The material for forming the substrate may be doped with p-type impurities or n-type impurities, or undoped. In addition, the substrate may be a bulk silicon substrate, a silicon-on-insulator (SOI) substrate, or a germanium-on-insulator (GOI) substrate. Other suitable materials for the substrate are within the contemplated scope of disclosure.

In some embodiments, the conductive feature 21 may be a conductive portion of a device (not shown) formed in front-end-of-line (FEOL) section (not shown) of the base structure 10. The device may be planar transistors, fin-type field-effect transistors (FinFET), nanosheet semiconductor devices (e.g. gate-all-around field-effect transistors (GAAFET), forksheet field-effect transistors, complementary field-effect transistors (CFET), or the like), capacitors, resistors, decoders, amplifiers, other suitable devices, and combinations thereof. The conductive portion may be a contact, e.g., a gate contact, a source/drain contact, or the like, of the device. Other suitable application of the conductive feature 21 are within the contemplated scope of disclosure. Only one conductive feature 21 is shown in FIG. 1, though there may be more than one conductive feature 21 present according to practical needs.

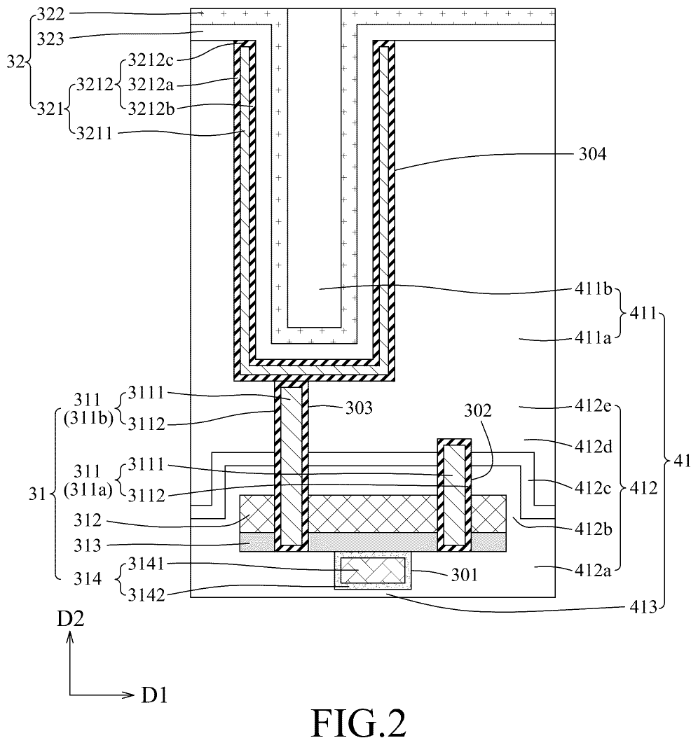

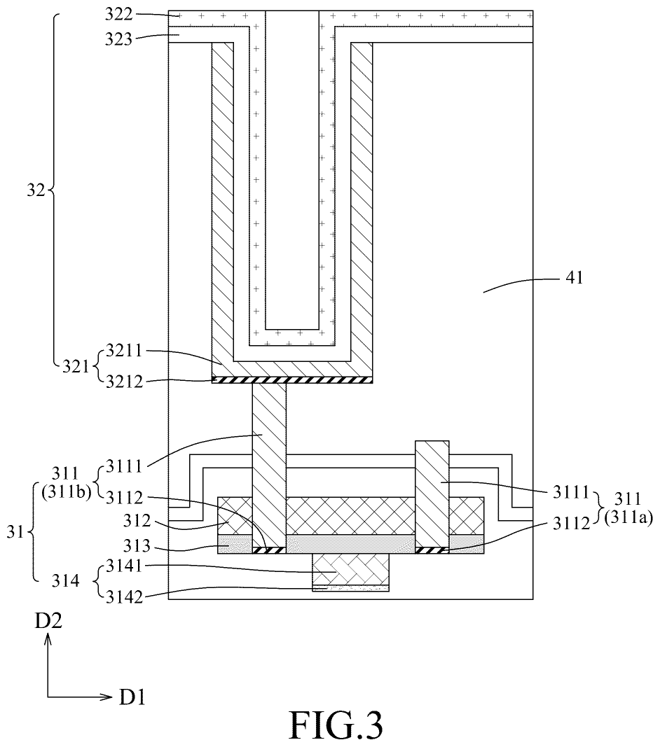

The back-end-of-line (BEOL) section 30 may include an interconnect structure including a plurality of transistors 31, a plurality of capacitors 32, and an interconnecting routing 33 connected to the conductive feature 21 through a routing (not shown) formed in the base structure 10. The transistors 31 are embedded in a middle portion 412 of an interlayer dielectric (ILD) 41. The capacitors 32 are embedded in an upper portion 411 of the ILD 41. The interconnecting routing 33 is embedded in the upper portion 411 of the ILD 41, the middle portion 412 of the ILD 41, and a lower portion 413 of the ILD 41, so as to connect different elements in the FEOL section and the BEOL section. For instance, the capacitors 32 may be each connected to a corresponding conductive feature 21 (one of which is shown in FIG. 1) located in the FEOL section through the interconnecting routing 33. In FIG. 1, the schematic view is a cross section of the structure that only shows the connection between the capacitors 32 and the interconnecting routing 33, while the connection between the conductive feature 21 and the interconnecting routing 33 is not shown. Similarly, the connection between the transistors 31 and the interconnecting routing 33 is not shown. One of the transistors 31 and a corresponding one of the capacitors 32 that are connected to each other are outlined by a dotted line and denoted as (X) in FIG. 1. FIG. 2 is an enlarged view of a region outlined by the dotted line (X) shown in FIG. 1, illustrating one of the transistors 31 and a corresponding capacitor 32 in accordance with some embodiments. FIGS. 3 to 7 are different variations of the structure shown in FIG. 2. The transistors 31 are described in terms of one transistor hereinafter. In some embodiments, the ILD 41 may include one of a low k dielectric material (such as silicon oxide, silicon nitride, silicon oxynitride, silicon carbonitride, silicon oxycarbide, silicon oxycarbonitride, silicon carbide, undoped silicate glass, boron carbon nitride, hydrogenated silicon oxycarbide, phosphosilicate glass, amorphous fluorinated carbon, borophosphosilicate glass, spin-on glass, fluorosilicate glass, xerogel, aerogel, parylene, divinylsiloxane-bis-benzocyclobutene-based dielectric material, bis-benzocyclobutenes, polyimide, non-porous materials, porous materials, the like, and combinations thereof.

In some embodiments, the transistor 31 may be a bottom-gate transistor. The bottom-gate transistor 31 includes two contact structures 311, a channel 312, a gate dielectric 313 and a gate electrode 314. The channel 312 has an upper surface and a lower surface opposite to each other. The gate dielectric 313 may serve as an insulator for insulating the gate electrode 314 from the contact structures 311 and the channel 312, and is disposed on the lower surface of the channel 312. The gate electrode 314 is disposed on the gate dielectric 313 opposite to the channel 312, and is connected to the interconnecting routing 33 (the connection is not shown in FIGS. 1 to 7). Each of the contact structures 311 has an upper part disposed on the upper surface of the channel 312. As shown in FIG. 1, in accordance with some embodiments, each of the contact structures 311 may further have a lower part that extends from the upper part through the channel 312 and the gate dielectric 313, to terminate at a lower end. The lower end is spaced apart from the gate electrode 314. In some embodiments, upper ends of the two contact structures 311 distal from the channel 312 are at different height levels.

In some embodiments, the channel 312 includes a metal oxide, such as indium gallium zinc oxide, indium oxide, gallium oxide, zinc oxide, tin oxide, copper oxide, or combinations thereof. Such channel 312 may react with contaminants, such as hydrogen, oxygen and water (but are not limited thereto), resulting in reduced bond strength of the metal oxide of the channel 312, or increased amount of defects (for example, dislocations or trap) within the channel 312, thus affecting reliability of the channel 312. Hydrogen may also undesirably alter electrical properties of the channel 312. Therefore, it is important for the channel 312 to be protected so as to prevent entry of the aforementioned contaminants into the channel 312, especially during fabrication of the semiconductor structure under high energy and/or temperature working condition.

In some embodiments, the gate dielectric 313 may be a low k dielectric material, such as silicon oxide, silicon nitride, silicon oxynitride, silicon carbonitride, silicon oxycarbide, silicon oxycarbonitride, silicon carbide, or combinations thereof, but are not limited thereto. In other embodiments, the gate dielectric 313 may be a high k dielectric material, such as hafnium oxide, zirconium oxide, zirconium aluminum oxide, hafnium aluminum oxide, hafnium silicon oxide, aluminum oxide, hafnium silicon oxynitride, hafnium tantalum oxide, hafnium titanium oxide, hafnium zirconium oxide, zirconium silicate, zirconium aluminate, titanium oxide, hafnium oxide-aluminum oxide alloy, or combinations thereof. Other suitable materials for forming the channel 312 and the gate dielectric 313 are within the contemplated scope of the present disclosure.

In the transistor 31, it is noted that each of the two contact structures 311 and the gate electrode 314 may serve as a conductive portion that is connected to the channel 312 (the two contact structures 311 are directly connected to the channel 312, while the gate electrode 314 is connected to the channel 312 through the gate dielectric 313). In some embodiments, the conductive portion may include a main body and a protection layer. The main body for the contact structures 311 may be a material with excellent electrical conductivity, and may include cobalt, copper, titanium, aluminum, titanium nitride, other suitable materials, or combinations thereof. The main body for the gate electrode 314 may be selected based on a designed threshold voltage of the transistor 31, and may include aluminum, copper, nickel, titanium nitride, tantalum nitride, metal silicide, other suitable materials, or combinations thereof. As such, the main body of each of the two contact structures 311 may be made of a material different from a material of the main body of the gate electrode 314. For each of the contact structures 311 and the gate electrode 314, the main body may have an electrical conductivity higher than an electrical conductivity of the protection layer. The protection layer is configured to prevent water and gases, such oxygen and hydrogen that are generated during fabrication of the semiconductor structure or that naturally exist in the environmental atmosphere, from diffusing into the channel 312 through the conductive portion and damaging the channel 312. Such protection layer is made of a material having a solid solubility lower than that of a material of the main body, and a hydrogen diffusion coefficient lower than a hydrogen diffusion coefficient of the material of the main body. In addition, it is desired that the material of the protection layer is conductive, so as to permit electrical conduction through the protection layer. In accordance with some embodiments, the protection layer may include a transition metal which is one of elements of groups 3 to 12 in periods 5 to 7, elements of lanthanide series, and elements of actinide series. Such transition metals are relatively heavier and have relatively larger atomic number to hinder diffusion of hydrogen. Examples of the transition metal include yttrium, zirconium, niobium, molybdenum, technetium, ruthenium, rhodium, palladium, silver, cadmium, lutetium, hafnium, tantalum, tungsten, rhenium, osmium, iridium, platinum, gold, mercury, lawrencium, rutherfordium, dubnium, seaborgium, bohrium, hassium, meitnerium, darmstadtium, roentgenium, copernicium, lanthanum, cerium, praseodymium, neodymium, promethium, samarium, europium, gadolinium, terbium, dysprosium, holmium, erbium, thulium, ytterbium, actinium, thorium, protactinium, uranium, neptunium, plutonium, americium, curium, berkelium, californium, einsteinium, fermium, mendelevium, and nobelium. In some embodiments, the transition metal is one of ruthenium, rhodium, palladium, iridium, and combinations thereof. Such transition metal permits the protection layer to have a relatively low solid solubility, and a relatively low hydrogen diffusion coefficient.

In some embodiments, the protection layer has a portion disposed between the channel and the main body. In other embodiments, the protection layer has a portion disposed on the main body opposite to the channel. In some other embodiments, the protection layer has a portion disposed on a sidewall of the main body. In certain embodiments, the protection layer has combination(s) of the aforementioned configurations. In yet other embodiments, the protection layer may partially surround, or fully enclose the main body.

In some embodiments, the protection layer is formed with a thickness ranging from about 0.5 nm to about 480 nm, such as about 0.5 nm to about 24 nm, or about 48 nm to about 480 nm. One may determine the thickness of the protection layer according to practical needs.

In accordance with some embodiments, referring to FIG. 2, the contact structures 311 may be configured as a full-protection type of contact structures 311 (i.e., in each of the contact structures 311, the protection layer 3112 fully encloses the main body 3111). Specifically, the protection layer 3112 has an upper part, a lower part opposite to the upper part, and a sidewall part interconnecting the upper part and the lower part. The upper part, the lower part, and the sidewall part respectively covering an upper surface, a lower surface and a sidewall of the main body 3111. Similarly, the gate electrode 314 may also be configured as a full-protection type by including the protection layer 3142 (similar to the protection layer 3112 of each of the contact structures 311) enclosing the main body 3141 (similar to the main body 3111 of each of the contact structures 311).

In accordance with some embodiments, for a bottom protection type of the conductive portion, the protection layer is located on the lower surface of the main body. For instance, referring to FIG. 3, each of the contact structures 311 has the protection layer 3112 located on the lower surface of the main body 3111, and the gate electrode 314 has the protection layer 3142 located on a lower surface of the main body 3141.

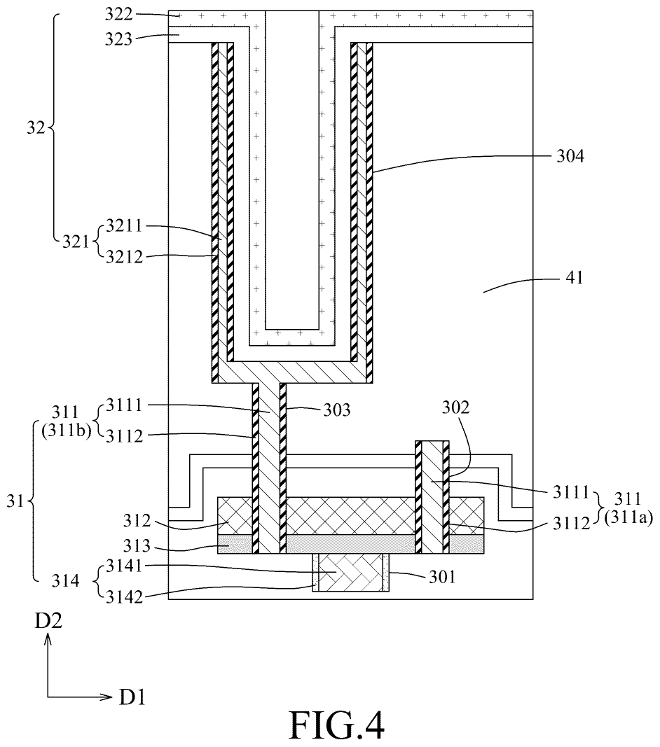

In accordance with some embodiments, for a sidewall protection type of the conductive portion, the protection layer covers the sidewall of the main body. For instance, referring to FIG. 4, each of the contact structures 311 has the protection layer 3112 covering the sidewall of the main body 3111, and the gate electrode 314 has the protection layer 3142 covering a sidewall of the main body 3141.

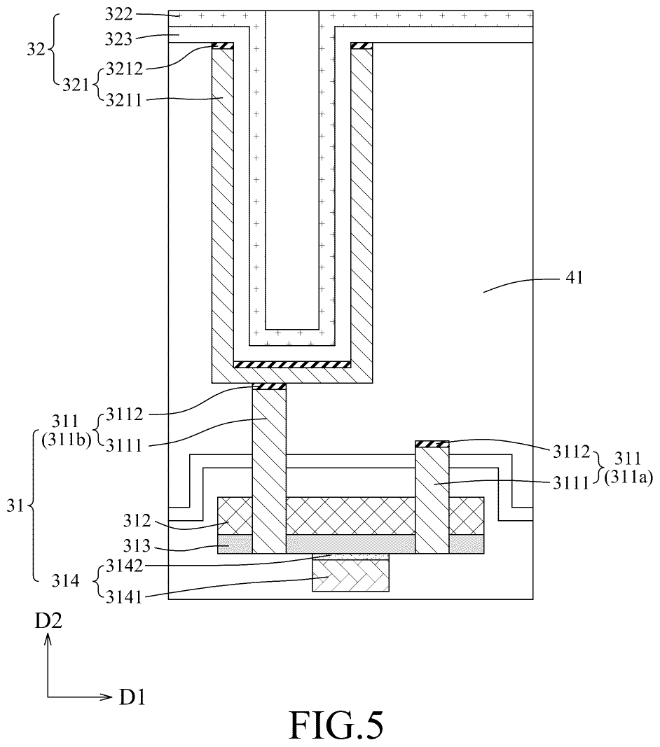

In accordance with some embodiments, for a cap protection type of the conductive portion, the protection layer serves as a cap to cover the upper surface of the main body. For instance, referring to FIG. 5, each of the contact structures 311 has the protection layer 3112 disposed on the upper surface of the main body 3111, and the gate electrode 314 has the protection layer 3142 disposed on an upper surface of the main body 3141.

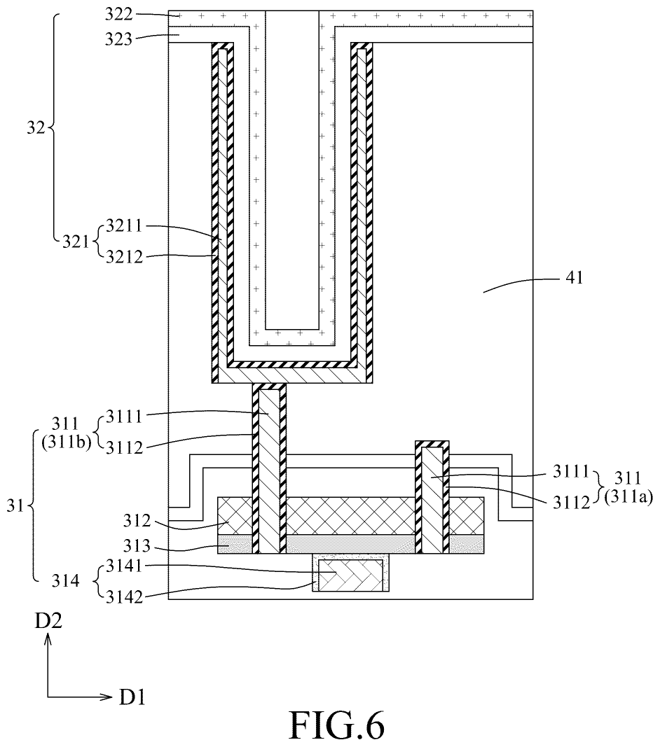

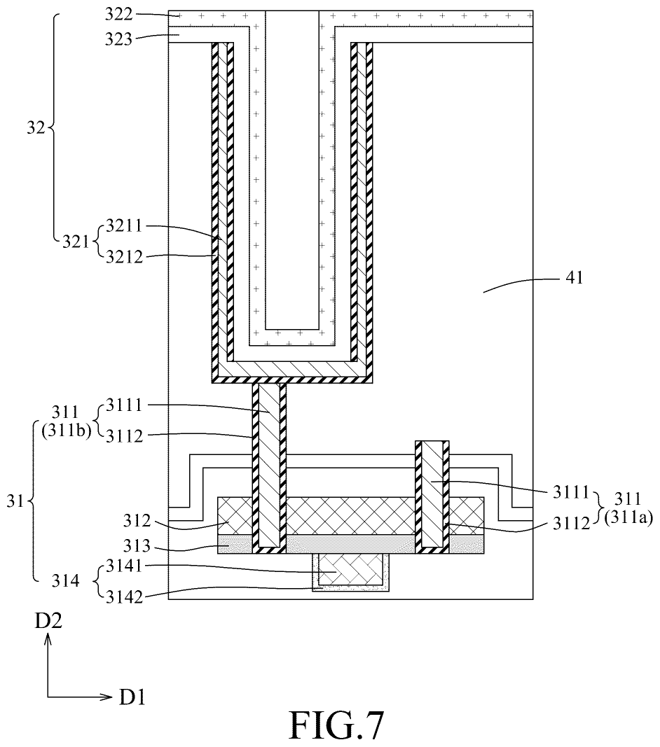

In accordance with some embodiments, the conductive portion may be configured as a semi-protection type by having the protection layer covering the sidewall, as well as one of the lower surface and the upper surface of the main body. For instance, referring to FIG. 6, each of the contact structures 311 has the protection layer 3112 disposed on the upper surface and the sidewall of the main body 3111, and the gate electrode 314 has the protection layer 3142 disposed on the upper surface and the sidewall of the main body 3141. Alternatively, referring to FIG. 7, each of the contact structures 311 has the protection layer 3112 disposed on the lower surface and the sidewall of the main body 3111, and the gate electrode 314 has the protection layer 3142 disposed on the lower surface and the sidewall of the main body 3141.

Please note that it is not necessary to have each of the contact structures 311 and the gate electrode 314 configured with the multi-layered structure including both the main body and the protection layer as shown in FIGS. 2 to 7. In some embodiments, only one of the contact structures 311 has the multi-layered structure. In other embodiments, both of the contact structures 311 have the multi-layered structure. In yet other embodiments, one of the contact structures 311 and the gate electrode 314 have the multi-layered structure. In some other embodiments, only the gate electrode 314 has the multi-layered structure. According to practical needs, those skilled in the art may decide which one(s) of the conductive portions (i.e., the two contact structures 311 and the gate electrode 314) having the multi-layered structure with which one of the protection types as described in the foregoing.

In accordance with some embodiments, the transistors 31 are each connected to a respective one of the capacitors 32. Each of the capacitors 32 includes a first electrode 321 connected to one of the two contact structures 311 of the respective transistor 31, a second electrode 322 connected to the interconnecting routing 33, and a dielectric 323 interposed between the first electrode 321 and the second electrode 322. In this case, the first electrode 321 of each of the capacitors 32 is connected to the left contact structure 311 of the respective transistor 31, but is not limited thereto. The capacitors 32 are described in terms of one capacitor hereinafter.

As shown in FIGS. 2 to 7, in accordance with some embodiments, the capacitor 32 may also have the first and/or second electrodes 321, 322 being configured as the multi-layered conductive portion. In the exemplary embodiments, shown in each of FIGS. 2 to 7, only the first electrode 321 is configured as the multi-layered conductive portion. In other embodiments, the second electrode 322 may also be configured as the multi-layered conductive portion. The first electrode 321 of the capacitor 32 shown in each of FIGS. 2 to 7 is designed to have a main body 3211 and a protection layer 3212. The main body 3211 of the capacitor 32 may be made of a material, and may be prepared similar to, or same as those of the main body 3111 of the contact structures 311 and/or the main body 3141 of the gate electrode 314. The protection layer 3212 of the capacitor 32 may be made of a material, and may be prepared similar to, or same as those of the protection layer 3112 of the contact structures 311 and/or the protection layer 3142 of the gate electrode 314. Thus, the materials and configurations of the main body 3211 and the protection layer 3212 of the capacitor 321 are not repeated for the sake of brevity. The main body 3211 of the capacitor 32 may have an electrical conductivity higher than an electrical conductivity of the protection layer 3212 of the capacitor 32. In some embodiments, the second electrode 322 may include a material similar to the material of the main body 3111 of the contact structures 311 and/or the main body 3141 of the gate electrode 314. In other embodiments, the dielectric 323 may be a low k dielectric material, such as silicon oxide, silicon nitride, silicon oxynitride, silicon carbonitride, silicon oxycarbide, silicon oxycarbonitride, silicon carbide, or combinations thereof, but are not limited thereto. In other embodiments, the dielectric 323 may be a high k dielectric material, such as hafnium oxide, zirconium oxide, zirconium aluminum oxide, hafnium aluminum oxide, hafnium silicon oxide, aluminum oxide, hafnium silicon oxynitride, hafnium tantalum oxide, hafnium titanium oxide, hafnium zirconium oxide, zirconium silicate, zirconium aluminate, titanium oxide, hafnium oxide-aluminum oxide alloy, or combinations thereof. Other suitable materials for forming the second electrode 322 and/or the dielectric 323 are within the contemplated scope of the present disclosure.

In some embodiments, for the capacitor 32 and the transistor 31, each of the protection layers 3212 and 3112 is made of one of ruthenium, rhodium, palladium, or iridium and combinations thereof, and each of the main bodies 3211 and 3111 is made of copper or titanium nitride.

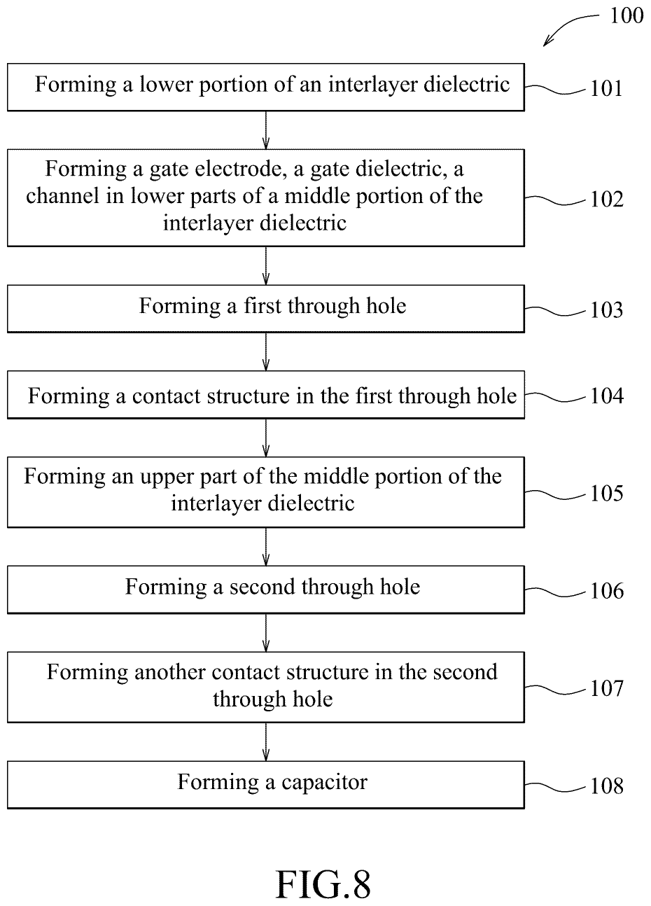

FIG. 8 is a flow diagram illustrating a method 100 for manufacturing the semiconductor structure (shown in FIGS. 1 and 2) in accordance with some embodiments. Additional steps can be provided before, after or during the method, and some of the steps described herein may be replaced by other steps or be eliminated.

Refers to the transistors 31 shown in FIGS. 1 and 2, and the flow diagram show in FIG. 8, the method 100 begins as step 101 where the lower portion 413 of the ILD 41 (located beneath the transistor 31) is formed on the base structure 10. A lower portion of the interconnecting routing 33 that is designed to be connected to the transistors 31, the conductive feature 21, or any other electronic devices is also formed during formation of the lower portion 413 of the ILD 41. The lower portion 413 of the ILD 41 may be formed using a plurality of deposition processes (e.g., chemical vapour deposition (CVD), atomic layer deposition process (ALD), physical vapour deposition (PVD)), and the lower portion of the interconnecting routing 33 may be formed in the lower portion 413 of the ILD 41 using single damascene processes, dual damascene processes, combinations thereof, or other suitable processes that are commonly known techniques of the art.

Referring to FIG. 8 and the example shown in FIG. 2, the method 100 then proceeds to step 102, where the gate electrode 314, the gate dielectric 313, and the channel 312 are formed. Referring to FIG. 2, in some embodiments, the middle portion 412 includes five parts 412a to 412e which are sequentially formed on the lower portion 413 of the ILD 41 in step 102 and step 105. In some embodiments, step 102 includes sub-steps of: (i) depositing the part 412a on the lower portion 413 of the ILD 41; (ii) patterning the part 412a to form a cavity 301; (iii) sequentially depositing a first material layer, a second material layer and a third material layer over the patterned part 412a so as to fill the cavity 301, the first and third material layers being conformally deposited for forming the protection layer 3142 of the gate electrode 314, the second material layer being used for forming the main body 3141 of the gate electrode 314 and being formed using, for example, a deposition-etching-deposition process; (iv) performing a planarization process to remove excesses of the first and third material layers and to expose the patterned part 412a such that the first and third material layers are formed into the protection layer 3142 and the second material layer serves as the main body 3141, thereby obtaining the gate electrode 314; (v) sequentially depositing a fourth material layer for forming the gate dielectric 313 and a fifth material layer for forming the channel 312 over the patterned part 412a; (vi) patterning the fourth and fifth material layers into the gate dielectric 313 and the channel 312; (vii) sequentially depositing the parts 412b, 412c, 412d over the patterned part 412a to cover the gate dielectric 313 and the channel 312; and (viii) performing another planarization process such that the part 412d has a flat surface. In step 102, the deposition processes may include chemical vapour deposition (CVD), atomic layer deposition process (ALD), physical vapour deposition (PVD), combinations thereof, or other suitable processes; the patterning processes may include photolithography processes, etching processes (e.g., wet etching, dry etching), or other suitable processes; and the planarization processes may include chemical mechanical polishing (CMP) processes or other suitable processes. In some embodiments, a material of the part 412c is different from materials of the lower portion 413, the upper portion 411, and the parts 412a, 412b, 412d, and 412e.

Referring to FIG. 8 and the example shown in FIG. 2, the method 100 then proceeds to step 103, where a first through hole 302 (for accommodating a smaller one of the contact structures 311, which is also denoted by 311a) is formed to extend through the parts 412d, 412c, 412b, the channel 312 and the gate dielectric 313 and to expose the channel 312. In some embodiments, step 103 may include photolithography processes, etching processes (e.g., wet etching, dry etching), or other suitable processes.

Referring to FIG. 8 and the example shown in FIG. 2, the method 100 then proceeds to step 104, where the contact structure 311a is formed filling the first through hole 302. It is noted that the lower end of the contact structure 311a is formed spaced apart from the gate electrode 314. The contact structure 311a may be formed in the first through hole 302 in a manner similar to sub-steps (iii) and (iv) of step 102 for forming the gate electrode 314 in the cavity 301, and thus details thereof are omitted.

Referring to FIG. 8 and the example shown in FIG. 2, the method 100 then proceeds to step 105, where the part 412e is formed covering the part 412d and the contact structure 311a using a suitable deposition process, such as chemical vapour deposition (CVD), atomic layer deposition process (ALD), physical vapour deposition (PVD), or combinations thereof.

Referring to FIG. 8 and the example shown in FIG. 2, the method 100 then proceeds to step 106, where a second through hole 303 (for accommodating a larger one of the contact structures 311, which is also denoted by 311b) is formed to extend through the parts 412e, 412d, 412c, 412b, the channel 312 and the gate dielectric 313 and to expose the channel 312. In some embodiments, step 106 may include photolithography processes, etching processes (e.g., wet etching, dry etching), or other suitable processes.

Referring to FIG. 8 and the example shown in FIG. 2, the method 100 then proceeds to step 107, where the contact structure 311b is formed filling the second through hole 303. Formation of the contact structure 311b is similar to formation of the contact structure 311a, and thus details thereof are omitted for the sake of brevity.

During performing steps 102 to 107, a middle portion of the interconnecting routing 33 (see FIG. 1) are also formed using single damascene processes, dual damascene processes, combinations thereof, or other suitable processes that are commonly known techniques of the art.

Referring to FIG. 8 and the example shown in FIG. 2, the method 100 then proceeds to step 108, where the capacitor 32 is formed in the upper portion 411 of the ILD 41. In some embodiments, as shown in FIG. 2, the protection layer 3212 includes an outer part 3212a, an inner part 3212b, and a cap part 3212c. The upper portion 411 includes two parts 411a, 411b. In some embodiments, referring to FIG. 2, step 108 includes sub-steps of: (i) depositing the part 411a over the middle portion 412; (ii) patterning the part 411a to form a trench 304; (iii) sequentially depositing a first film, a second film, and a third film (not shown, for forming the outer part 3212a, the main body 3211, and the inner part 3212b, respectively) over the part 411a along inner surfaces of the trench 304; (iv) performing a planarization process to remove excesses of the first, second and third films and to expose the part 411a such that the first and third films are formed into the outer and inner parts 3212a, 3212b of the protection layer 3212 for sandwiching the planarized second film; (v) etching back the planarized second film to form the main body 3211; (vi) forming a cap layer (not shown) to covering the main body 3211, followed by a planarization process to expose the part 411a such that the cap layer is formed into the cap part 3212c, thereby obtaining the first electrode 321; (vii) forming the dielectric 323 and the second electrode 322 over the first electrode 321 and the part 411a by suitable deposition processes and patterning processes; and (viii) forming the part 411b over the second electrode 322 (see also FIG. 1). In step 108, the deposition processes may include chemical vapour deposition (CVD), atomic layer deposition process (ALD), physical vapour deposition (PVD), combinations thereof, or other suitable processes; the patterning or etch-back processes may include photolithography processes, etching processes (e.g., wet etching, dry etching), or other suitable processes; and the planarization processes may include chemical mechanical polishing (CMP) processes or other suitable processes. In step 108, an upper portion of the interconnecting routing 33 is also formed in the parts 411a, 411b using single damascene processes, dual damascene processes, combinations thereof, or other suitable processes that are commonly known techniques of the art.

It is noted that the gate electrode 314 formed in step 102, the contact structure 311a formed in step 104, the contact structure 311b formed in step 107, and the first electrode 321 of the capacitor 32 formed in step 108 are each configured as a full-protection type (see FIG. 2). Those steps may be modified for obtaining the structure shown in FIGS. 3 to 7. For example, in FIG. 3, each of the protection layers 3142, 3112, 3212 may be formed using a deposition-etching-deposition process to have a desired thickness, and then a corresponding one of the main bodies 3141, 3111, 3211 is formed thereon. In FIG. 4, a material layer for forming each of the protection layers 3142, 3112, 3212 may be first formed on a bottom surface of the cavity 301, the first and second through holes 302, 303 or trench 304 by PVD, and is then subjected to bombardment such that the material layer is resputtered onto a sidewall of the cavity 301, the first and second through holes 302, 303 or trench 304. In FIG. 5, each of the main bodies 3141, 3111, 3211 may be formed by a deposition process and an etch back process, and a corresponding one of the protection layers 3142, 3112, 3212 may be formed thereon by a suitable process (e.g., a selective deposition process). The protection layers 3142, 3112, 3212 in FIG. 6 are respectively formed in a manner similar to those shown in FIG. 2, except that a bottom portion of each of the protection layers 3142, 3112, 3212 is selectively removed using a suitable process, e.g., an anisotropic etching. In FIG. 7, each of the protection layers 3142, 3112, 3212 may be formed in a manner similar to those shown in FIG. 4, except that the strength of bombardment may be adjusted to determine whether the material layer has a portion left on the bottom or not. Formation of the protection layers 3112 of the contact structures 311, the protection layer 3142 of the gate electrode 314 of the transistor 31, and the protection layer 3212 of the first electrode 321 of the capacitor 32 are compatible with low temperature processed BEOL process.

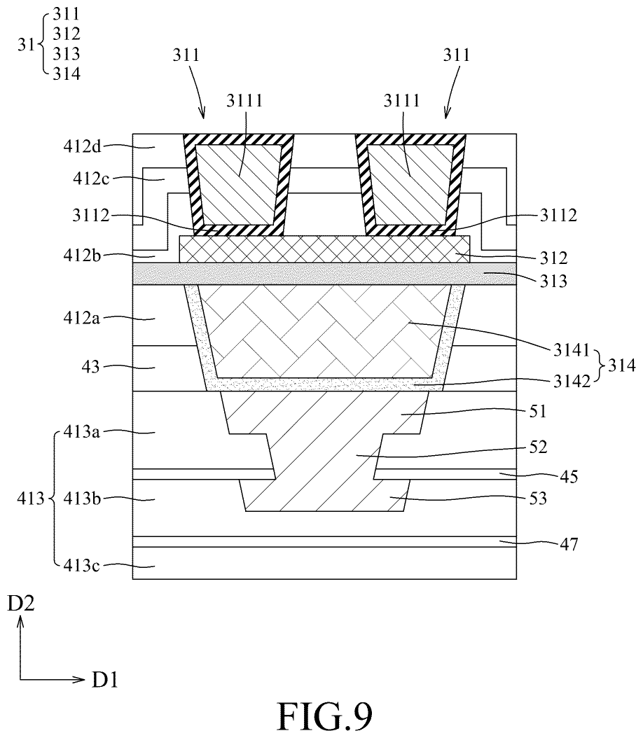

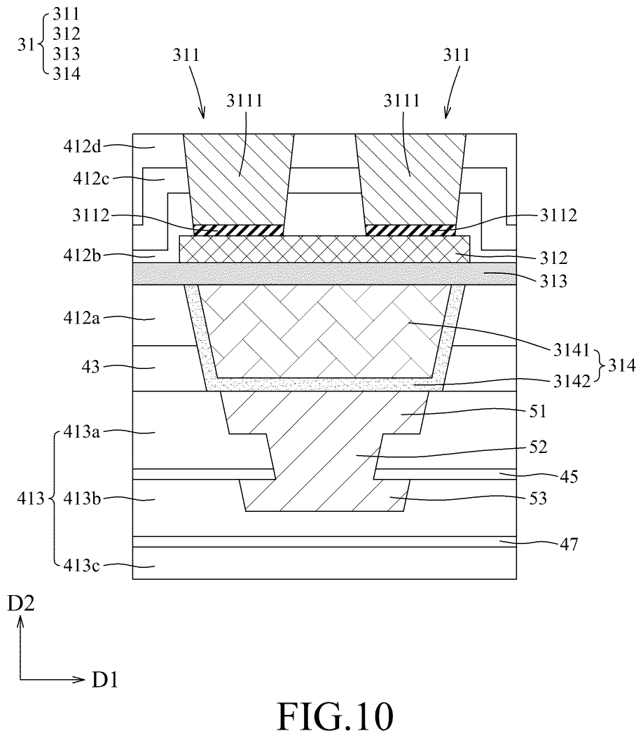

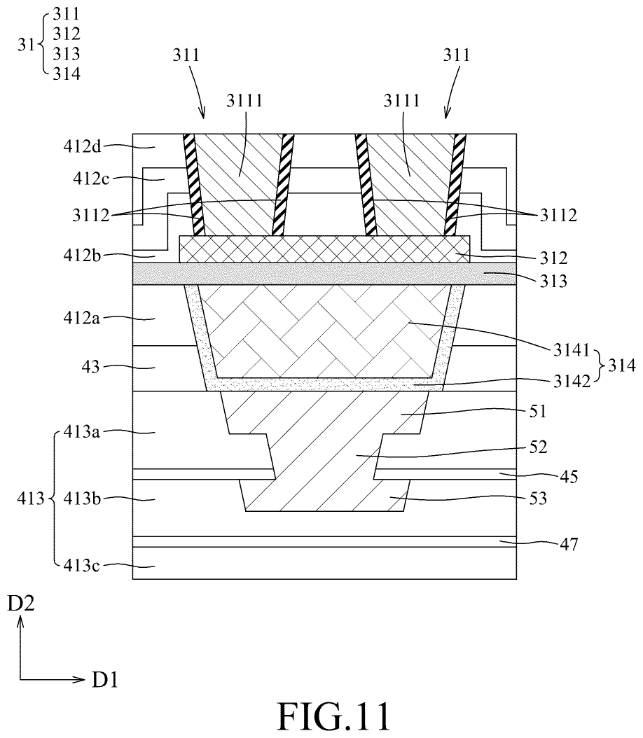

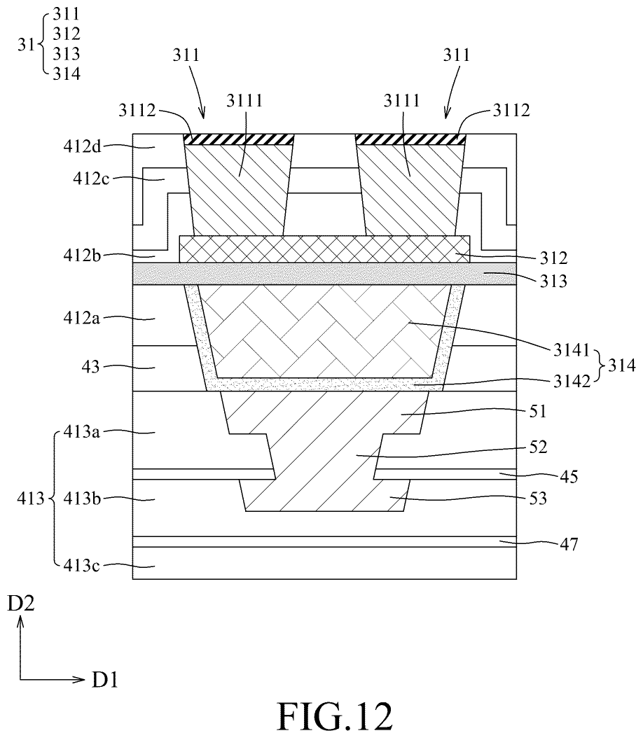

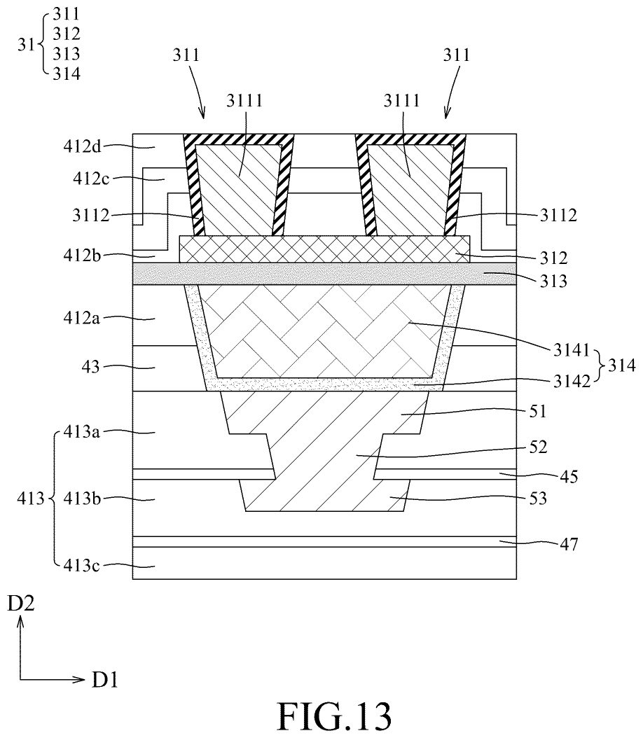

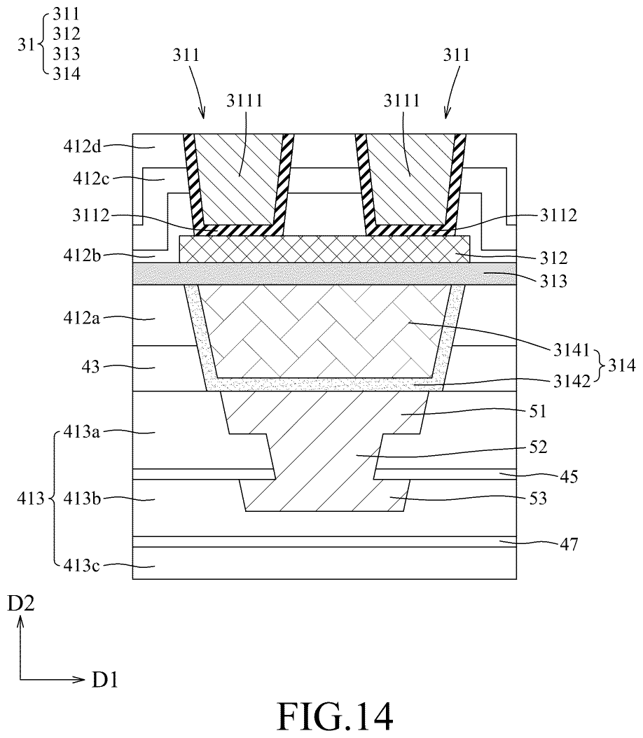

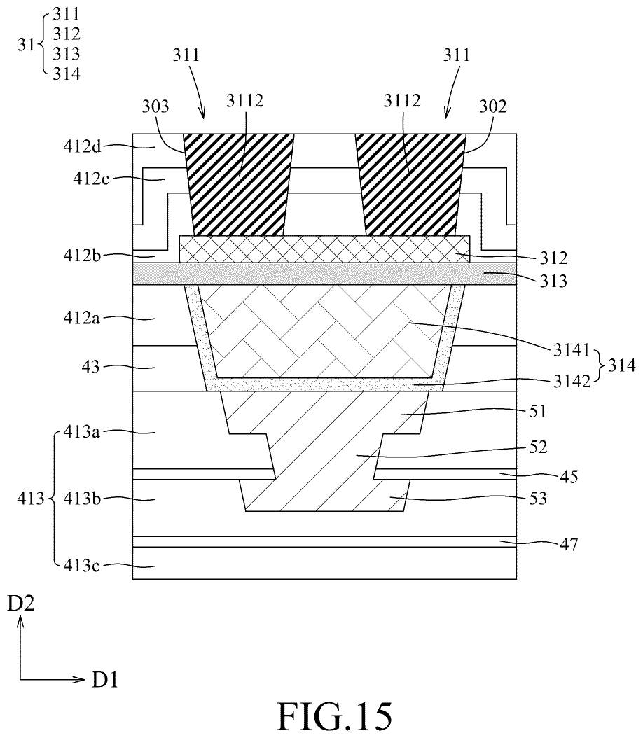

FIGS. 9 to 15 illustrate other variations of the bottom-gate transistor 31 in accordance with some embodiments. The contact structures 311 shown in FIGS. 9 to 14 are respectively similar to those shown in FIGS. 2 to 7. The contact structures 311 shown in FIG. 15 is configured as a plug protection type in which each of the contact structures 311 includes merely the protection layer 3112, while the main body is omitted. Such configuration is especially useful when the contact structures 311 are designed to have a relatively small thickness, and it would be much easier to manufacture a single-layer structure, i.e., the protection layer within the small thickness, instead of to manufacture the multi-layered structure. To obtain the structure shown in FIG. 15, after forming the through holes 302, 303 in the parts 412d, 412c, and 412b, a material for forming the protection layer 3142 is deposited to fill the through holes and over the part 412d, followed by a planarization process (e.g., CMP) so as to obtain the contact structures 311 shown in FIG. 15.

Referring to FIGS. 9 to 15, in accordance with some embodiments, the gate electrode 314 is formed with a width measured along a first direction D1 greater than a separation distance between the two contact structures 311. In such case, each of the contact structures 311 does not penetrate through the channel 312 or the gate dielectric 313. That is, each of the contact structures 311 merely have the upper part, and the lower end of each of the contact structures 311 terminates at the upper surface of the channel 312. In some embodiments, the upper ends of the two contact structures 311 distal from the channel 312 are at the same height, and one of the two contact structures 311 is connected to the capacitor 32 (see FIGS. 2 to 7) through metal line(s) and/or metal vias(s) (not shown). In addition, in some embodiments, as shown in FIGS. 9 to 15, the gate dielectric 313 may have a length greater than that of the channel 312. In some other embodiments, the gate dielectrics 313 of adjacent ones of the transistors 31 (only one of which is shown) are connected to each other to form a continuous structure. Although the gate electrode 314 shown in each of FIGS. 9 to 15 has a configuration similar to that shown in FIG. 7 (i.e., the protection layer 3142 of the gate electrode 314 is disposed on the lower surface and the sidewall of the main body 3141), the gate electrode 314 may have other configurations similar to those shown in FIGS. 2 to 6. In some embodiments, elements denoted with the numerals 43, 45, 47 are etch stop layers (ESLs). Examples of a dielectric material of the ESLs 43, 45, 47 are metal nitride, metal oxide, metal carbide, silicon nitride, silicon oxide, silicon carbide, silicon oxynitride, or combinations thereof. Other suitable materials for the ESL 43, 45, 47 are within the contemplated scope of the present disclosure. In the exemplary embodiments shown in FIGS. 9 to 15, the lower portion 413 of the ILD 41 may include parts 413a, 413b, 413c that are disposed alternating with the ESLs 43, 45, 47 in a second direction D2 and that are made of a material different from those of the other portions or parts of the ILD 41, though in some other embodiments, the parts 413a, 413b, 413c may be made of a material same as those of the other portions or parts of the ILD 41.

In the exemplary embodiments shown in FIGS. 9 to 15, the lower portion of the interconnecting routing 33 (see also FIG. 1) located at the lower portion 413 of the ILD 41 may include metal lines 51, 53, and a via 52, or any other suitable interconnecting elements that are connected to the gate electrode 314 of the transistor 31, so that the transistor 31 may be connected to the other electronic elements in the semiconductor structure through the interconnecting routing 33. As shown in FIGS. 9 to 15, the gate electrode 314 penetrates through the ESL 43 to be connected to the metal line 51. In some embodiments, the interconnecting routing 33 (including the metal lines 51, 53, and the via 52) may each have configuration(s) and material(s) similar to the contact structures 311 of the transistor 31 (e.g., each of the metal lines 51, 53, and the via 52 may include a main body and a protection layer), and are not discussed for the sake of brevity.

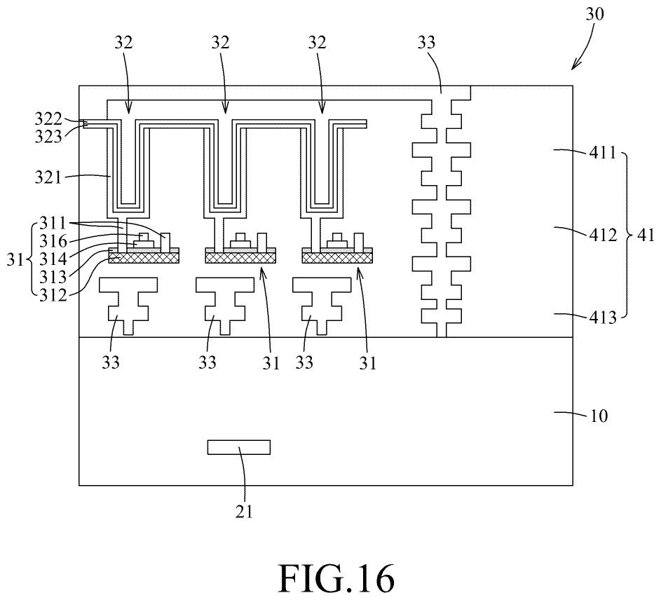

In accordance with some embodiments, FIG. 16 illustrates another semiconductor structure similar to that shown in FIG. 1, except that in FIG. 16, each of the transistors 31 is a top-gate transistor. The transistors 31 are described in terms of one transistor hereinafter. The capacitors 32 and the interconnecting routing 33 shown in FIG. 16 are similar to those shown in FIG. 1, and thus the configurations and the materials thereof are not discussed for the sake of brevity.

In the top-gate transistor 31, the gate dielectric 313 is disposed on the upper surface of the channel 312. The contact structures 311 penetrate the gate dielectric 313 to be connected to the upper surface of the channel 312, and are spaced apart from each other. The gate electrode 314 is disposed on the gate dielectric 313 opposite to the channel 312, and is spaced apart from and disposed between the contact structures 311. In the top-gate transistor 31, the gate electrode 314 and the contact structures 311 are disposed on the same side, i.e., the top side, of the channel 312. The gate electrode 314 is connected to the interconnecting routing 33 through a gate contact structure 316. The connection between the gate contact structure 316 and the interconnecting routing 33 is not shown in the cross-section shown in FIG. 16. The gate contact structure 316 may have a configuration and material similar to the contact structures 311 (e.g., the gate contact structure 316 may include a main body and a protection layer), and are not discussed for the sake of brevity.

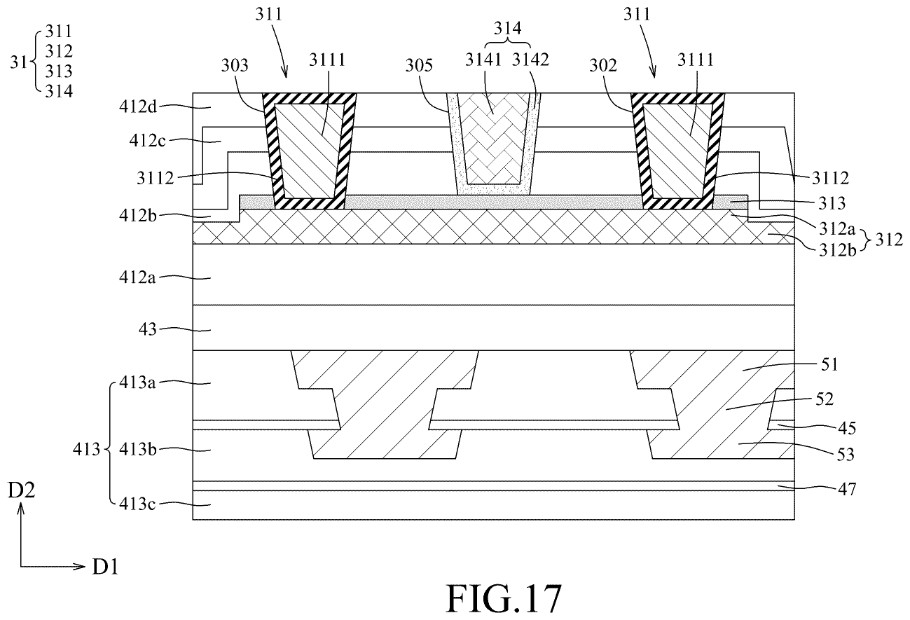

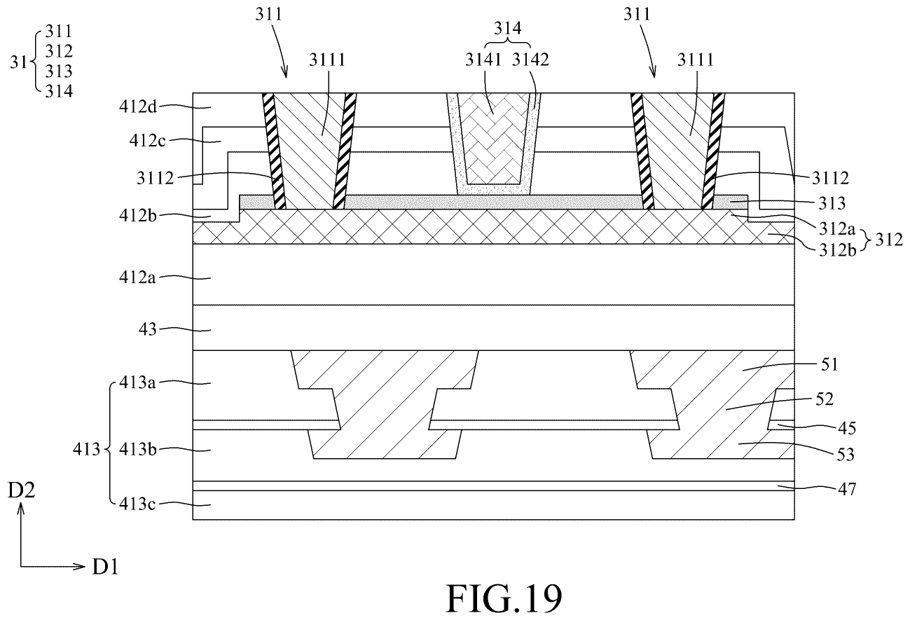

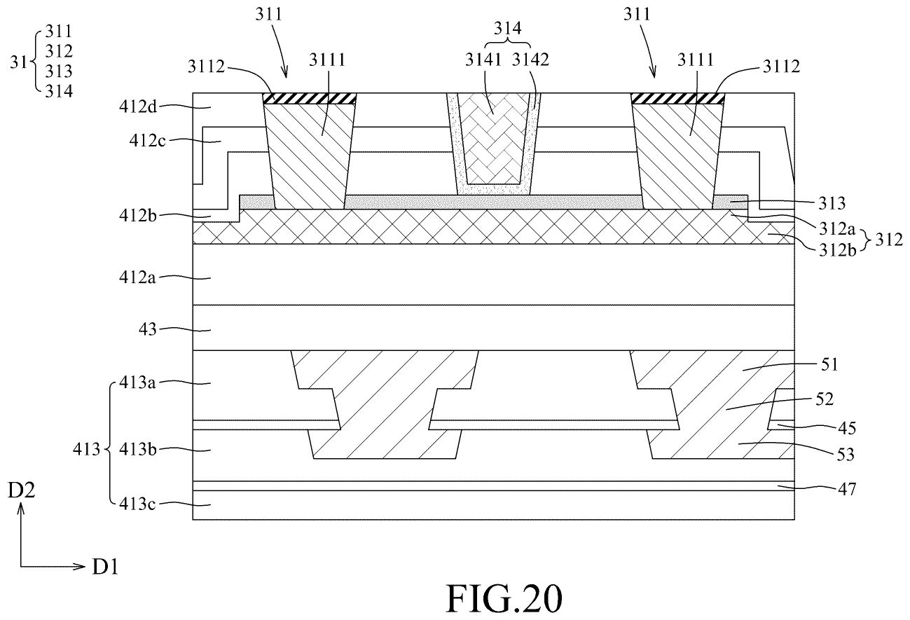

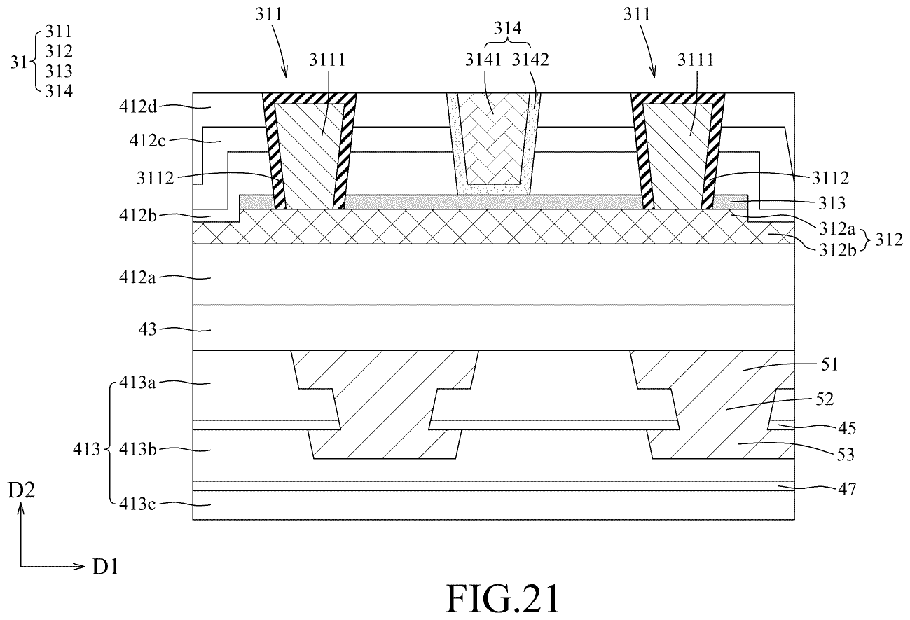

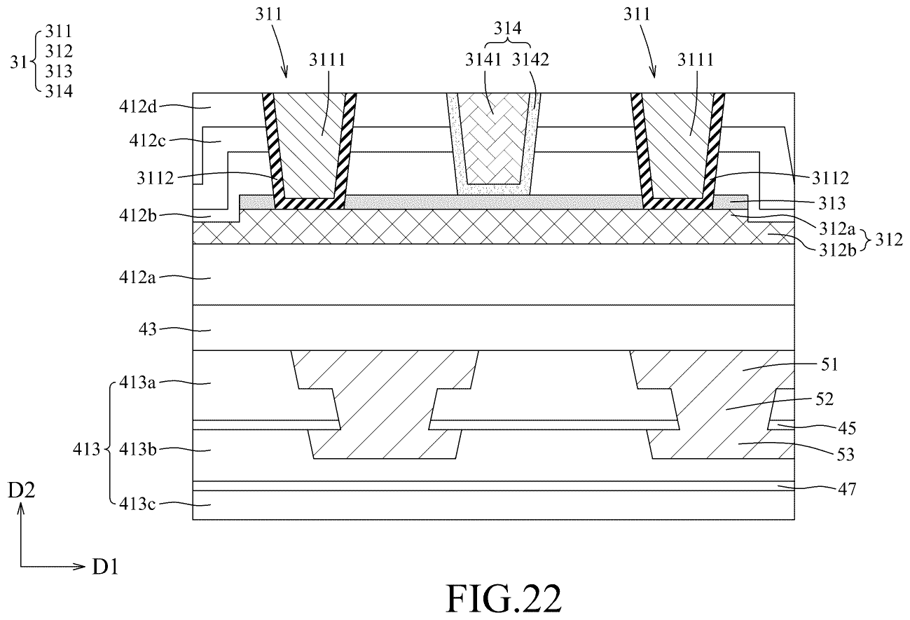

FIGS. 17 to 23 respectively illustrates different variations of the top-gate transistor 31 in accordance with some embodiments. The configurations and materials of the contact structures 311 and the gate electrode 314 of the transistors 31 shown in FIGS. 17 to 23 are respectively similar to those shown in FIGS. 9 to 15, and thus are not discussed for the sake of brevity. The gate contact structure 316 (see FIG. 16) is not shown in FIGS. 17 to 23.

It is noted that in each of the variations shown in FIGS. 17 to 23, the channel 312 has a step structure by having an upper part 312a with a smaller width connected to the gate dielectric 313 and the contact structures 311, and a lower part 312b with a larger width connected to the part 412a. The upper part 312a may have a sidewall flush with a sidewall of the gate dielectric 313.

The ESLs 43, 45, 47 and the lower portion 413 shown in FIGS. 17 to 23 are similar to those shown in FIGS. 9 to 15, and thus are not discussed for the sake of brevity.

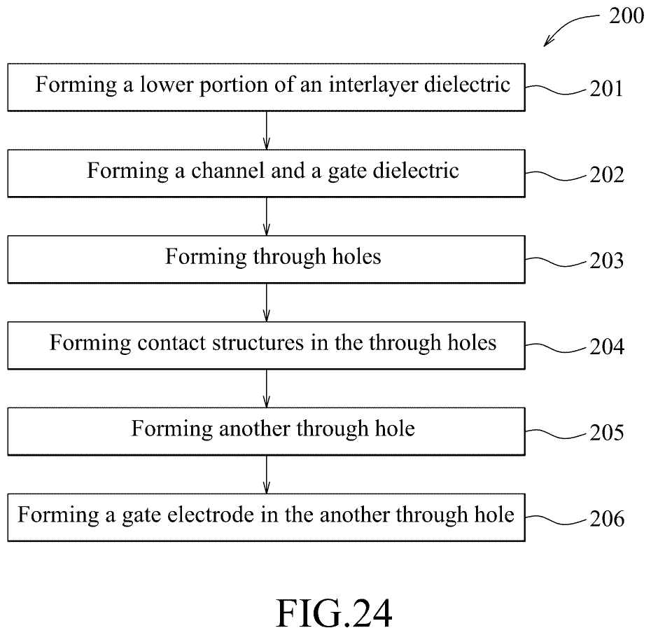

FIG. 24 is a flow diagram illustrating a method 200 for manufacturing the transistor 31 shown in FIG. 17 (as for the capacitors 32 shown in FIG. 16, manufacturing thereof is similar to step 108 described in the method 100, and thus is not repeated for the sake of brevity).

Referring to the transistor 31 shown in FIG. 17, and the flow diagram shown in FIG. 24, the method begins at step 201, where the lower portion 413 and the ESLs 43, 45, 47 are formed on the base structure 10 (see FIG. 16). In the exemplary example shown in FIG. 17, the part 413c, the ESL 47, the part 413b, the ESL 45, the part 413a of the lower portion 413, and the ESL 43 are sequentially formed on the base structure 10. The metal lines 51, 53 and the via 52 of the interconnecting routing 33 are formed during formation of the lower portion 413 of the ILD 41. The lower portion 413 of the ILD 41 and the ESLs 43, 45, 47 may be formed using a plurality of deposition processes (e.g., chemical vapour deposition (CVD), atomic layer deposition process (ALD), physical vapour deposition (PVD)), and the lower portion of the interconnecting routing 33 may be formed in the lower portion 413 of the ILD 41 and the ESLs 43, 45, 47 using single damascene processes, dual damascene processes, combinations thereof, or other suitable processes that are commonly known techniques of the art.

Referring to FIG. 24 and the example shown in FIG. 17, the method 200 then proceeds to step 202, where the channel 312 and the gate dielectric 313 are formed. In some embodiments, step 202 includes sub-steps of: (i) sequentially depositing the part 412a and a channel material layer for forming the channel 312 on the ESL 43, followed by patterning the channel material layer; (ii) depositing a gate dielectric layer for forming the gate dielectric 313 over the part 412a and the patterned channel material layer, followed by patterning the gate dielectric layer and the patterned channel material layer such that the gate dielectric layer is formed into the gate dielectric 313 and the patterned channel material layer is further patterned into the channel 312 with the step structure. The deposition process processes may include chemical vapour deposition (CVD), atomic layer deposition process (ALD), physical vapour deposition (PVD), combinations thereof, or other suitable processes. The etching processes may include wet etching, dry etching, or other suitable processes.

Referring to FIG. 24 and the example shown in FIG. 17, the method 200 then proceeds to step 203, where through holes 302, 303 for accommodating the contact structures 311 are formed. In some embodiments, step 203 includes sub-steps of: (i) forming parts 412b, 412c and 412d over the channel 312 and the gate dielectric 313; (ii) performing a planarization process such that the part 412d has a flat surface; and (iii) forming through holes 302, 303 which penetrate through the parts 412d, 412c, 412b and the gate dielectric 313 and which expose the channel 312. Sub-step (i) of step 203 may be performed by any suitable deposition processes such as chemical vapour deposition (CVD), atomic layer deposition process (ALD), physical vapour deposition (PVD), or combinations thereof in a conformal manner. Sub-step (ii) of step 203 may be performed using chemical mechanical polishing (CMP) processes or other suitable processes. Sub-step (iii) may include photolithography processes, etching processes (e.g., wet etching, dry etching), or other suitable processes.

Referring to FIG. 24 and the example shown in FIG. 17, the method 200 then proceeds to step 204, where the contact structures 311 are respectively formed and fill the through holes 302, 303. The contact structures 311a may be each formed in a manner similar to step 104 of the method 100, and thus details thereof are omitted.

Referring to FIG. 24 and the example shown in FIG. 17, the method 200 then proceeds to step 205, where a through hole 305 for accommodating the gate electrode 314 is formed. The through hole 305 penetrates through the parts 412d, 412c, and 412b and exposes the gate dielectric 313. In some embodiments, step 205 may include photolithography processes, etching processes (e.g., wet etching, dry etching), or other suitable processes.

Referring to FIG. 24 and the example shown in FIG. 17, the method 200 then proceeds to step 206, where the gate electrode 314 is formed and fills the through hole 305. In some embodiments, step 206 may include sub-steps of: (i) depositing a material layer for forming the protection layer 3142 on a bottom surface of the through hole 305 by PVD, (ii) subjecting the material layer to a bombardment such that a portion of the material layer is resputtered onto a sidewall of the through hole 305, and another portion of the material layer remains on the bottom surface; (iii) depositing a material layer for forming the main body 3141 filling the through hole 305 and over the part 412d; and (iv) performing a planarization process to remove an excess amount of the material layer for forming the main body 3141. In some other embodiments, step 206 may include sub-step of: (a) sequentially depositing material layers for forming the protection layer 3442 and the main body 3141 filling the through hole 305 and over the part 412d; and (b) performing a planarization process to remove an excess amount of the material layers. The deposition processes may include chemical vapour deposition (CVD), atomic layer deposition process (ALD), physical vapour deposition (PVD), combinations thereof, or other suitable processes. The planarization processes may include chemical mechanical polishing (CMP) processes or other suitable processes.

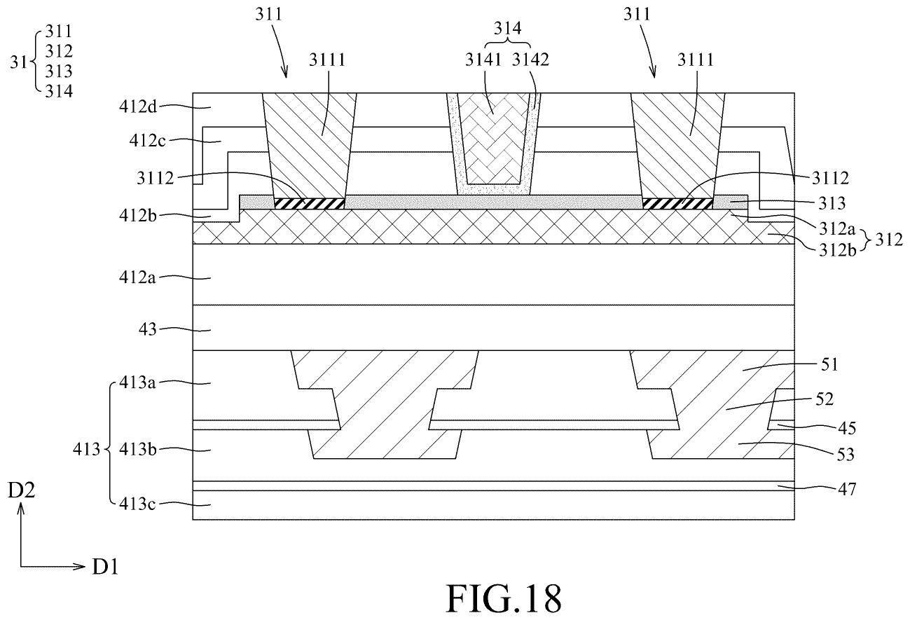

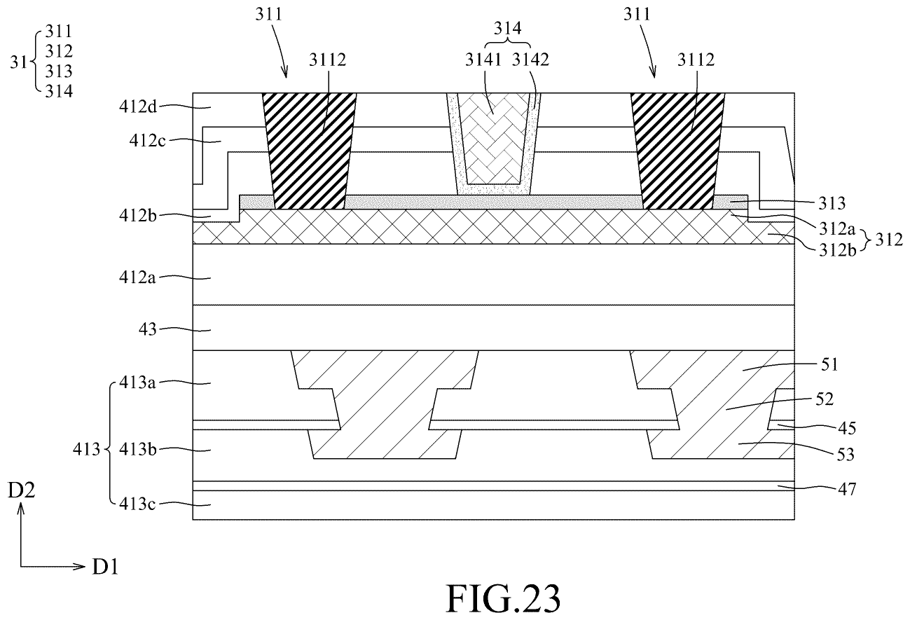

In some embodiments, steps 205 to 206 for forming the gate electrode 314 may be preformed prior to steps 203 to 204 for forming the contact structures 311. In addition, please note that step 204 may be modified to obtain different protection type of the contact structures 311 as discussed in the method 100 so as to obtain the structures shown in FIGS. 18 to 22. The contact structures 311 shown in FIG. 23 may be formed in a manner similar to that shown in FIG. 15. Although the gate electrode 314 shown in each of FIGS. 15 to 23 has a configuration similar to that shown in FIGS. 9 to 15 (i.e., the protection layer 3142 of the gate electrode 314 is disposed on the lower surface and the sidewall of the main body 3141), the gate electrode 314 may have other configurations similar to those shown in FIGS. 2 to 6.

In some embodiments, when the upper surfaces of the contact structures 311 are of the same height level, such contact structures 311 may be formed at the same time e.g., in steps 203 and 204 of the method 200. In other embodiments, when the upper surfaces of the contact structures 311 are not at the same height level, such contact structures 311 are formed one by one, e.g., in method 100, steps 103 and 104 for forming the contact structure 311a first, followed by step 105, and steps 106 to 107 for forming the contact structure 311b.

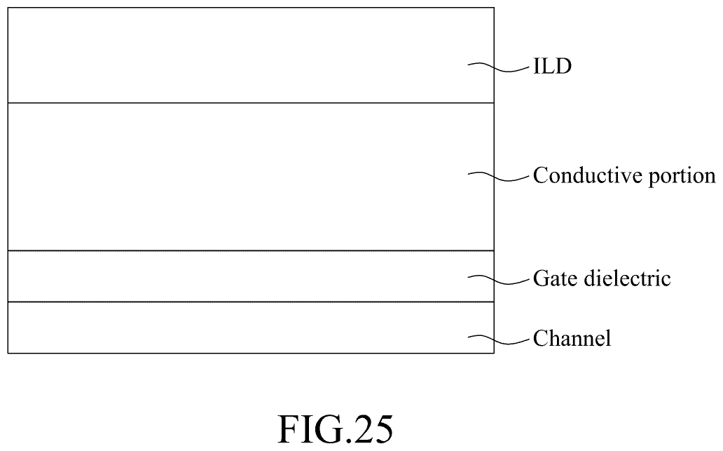

In the present disclosure, in order to protect the metal oxide channel 312 from contaminants which diffuse through any conductive portions and reaching the metal oxide channel 312, the conductive portions, such as the contact structures 311 and/or the gate electrode 314 are proposed to include the additional protection layer that includes the transition metal which is one of elements of groups 3 to 12 in periods 5 to 7, elements of lanthanide series, and elements of actinide series. In order to illustrate the effect of such protection layer, two groups of samples are prepared and subjected to a secondary ion mass spectrometry test. FIG. 25 is a schematic view illustrating a structure of the samples simulating a top-gate transistor. Referring to FIG. 25, each of the samples has a stack including four layers, namely, ILD, a conductive portion, a gate dielectric and a channel which are arranged in a top to bottom manner in such order. In each of the samples, the ILD, the gate dielectric and the channel are respectively made of an undoped silicate glass (USG), an insulating material, and a metal oxide, and which respectively correspond to the ILD 41, the gate dielectric 313, and the channel 312 of the transistor 31.

A first group of the samples respectively include, in the conductive portion, a single layer structure including titanium nitride (TiN, with no protection layer), a multi-layered structure including titanium nitride/titanium/titanium nitride (TiN/Ti/TiN, with Ti serving as the protection layer), and another multi-layered structure including titanium nitride/ruthenium/titanium nitride (TiN/Ru/TiN, with Ru serving as the protection layer). The thicknesses of the protection layers of the samples in the first group range from about 0.5 nm to about 24 nm. Such protection layers are considered as thin protection layers.

A second group of the samples respectively include, in the conductive portion, similar contents as those of the first group of the samples, expect that in the second group of the samples, the protection layer, if any is formed with a thickness greater than those of the first group of the sample. The thicknesses of the protection layers of the second group of the samples range from about 48 nm to about 480 nm. Such protection layers are considered as thick protection layers.

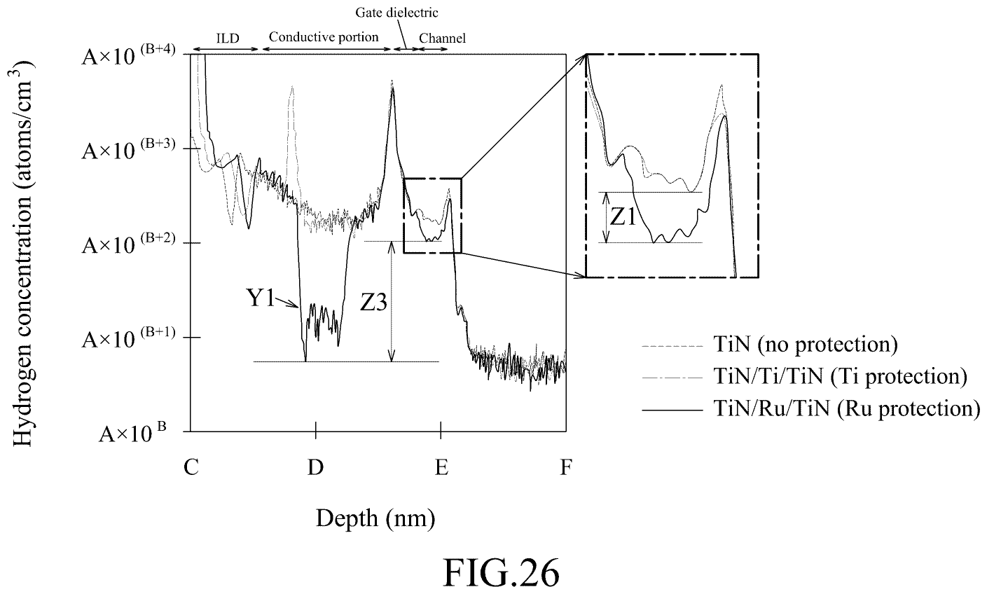

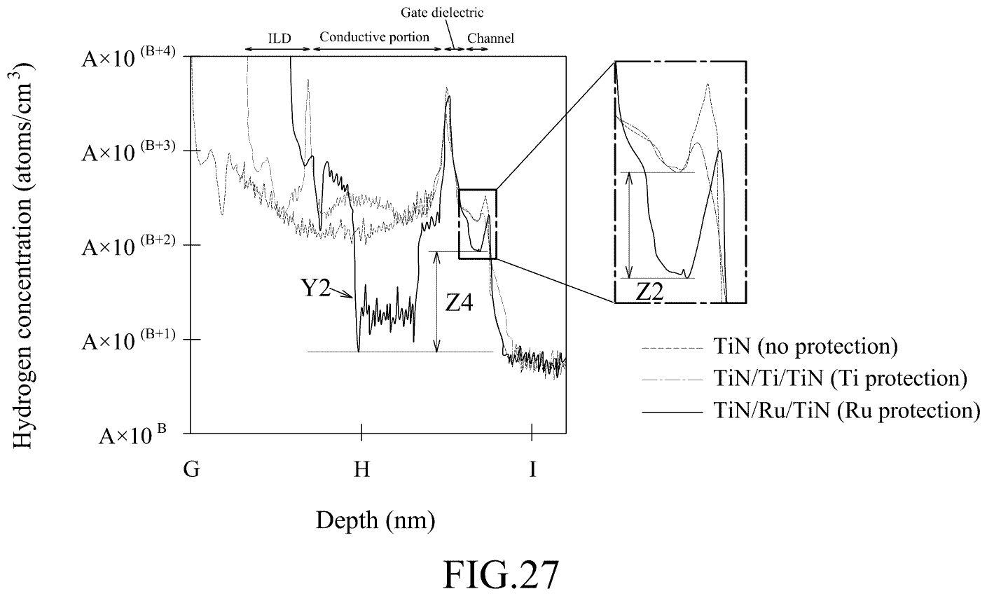

The two groups of samples are then subjected to the secondary ion mass spectrometry test. FIG. 26 is a diagram showing distribution of hydrogen concentration in the first group of samples, in which two of the samples are formed with a thin protection layer. FIG. 27 is a diagram showing distribution of hydrogen distribution in the second group of samples, in which two of the samples are formed with a thick protection layer. Referring to FIGS. 26 and 27, A and B each represents a positive integer, and the hydrogen concentrations are measured in atoms/cm³. C, D, E, F (see FIG. 26), G, H and I (see FIG. 27) are integers representing depth measured in nm and in a top to bottom manner. The values of C to F increase along the measuring direction, and the values of G to I increase along the measuring direction.

Referring to FIG. 26, for the first group of samples, it is noted that at the channel region (see the enlarged view enclosed in dotted line), hydrogen concentration of the sample having the Ti protection layer is similar to hydrogen concentration of the sample without any protection layer, indicating that the Ti protection layer is not effective in lowering the hydrogen concentration of the channel region. In contrast, the sample having Ru as the protection layer has a hydrogen concentration of the channel region significantly lower than a hydrogen concentration of each of channel regions of the other samples. Comparing the two transition metal protection layers, Ti is an element of period 4, while Ru is an element of period 5 and has an atomic number larger than that of Ti. Ru is more effective in hindering contaminants, such as hydrogen gas, from diffusing through the conductive portion and entering the channel, thereby being effective in lowering hydrogen concentration of the channel region.

Referring to FIG. 27, for the second group of samples having thicker protection layers (in comparison with the first group of samples), the trend of the hydrogen concentration distribution at the channel regions is similar to the trend shown in FIG. 26, and the sample having Ru as the protection layer has a hydrogen concentration of the channel region significantly lower than a hydrogen concentration of each of channel regions of the other samples.

Referring to FIG. 26, for the first group of samples, a first difference of hydrogen concentration at the channel region between the sample having thinner Ru protection layer and the sample without any protection is Z1. Referring to FIG. 27, for the second group of samples, a second difference of hydrogen concentration at the channel region between the sample having thicker Ru protection layer and the sample without any protection is Z2. It is noted that the second difference Z2 is greater than the first difference Z1, indicating that the sample having thicker Ru protection layer is more effective in hindering hydrogen diffusion, so that the channel region of the sample with thicker Ru protection layer achieve a lower hydrogen concentration. Furthermore, in the sample having the Ru protection layer, even though the TiN layers are not fully enclosed by the Ru protection layer and the Ru protection layer is not in direct contact with the channel region, the Ru protection layer still can effectively hinder diffusion of hydrogen into the channel region. As such, based on the above results, the channel 312 in each of the abovementioned embodiments shown in FIGS. 1 to 7 and 9 to 23 should also have a reduced hydrogen concentration.

In addition, as shown in each of FIGS. 26 and 27, for the sample having the Ru protection layer, at the conductive portion, a section (Y1, Y2) having significantly low hydrogen concentration is observed. Such section is believed to correspond to the Ru protection layer. A difference (Z3, Z4) between the hydrogen concentration of the Ru protection layer and the hydrogen concentration of the channel section may be greater than one order of magnitude.

The embodiments of the present disclosure have the following advantageous features. The protection layers 3112 in the contact structures 311 and/or the protection layer 3142 in the gate electrode 314 of the transistor 31 include a transition metal which is one of elements of groups 3 to 12 in periods 5 to 7, elements of lanthanide series, and elements of actinide series. Such transition metal has relatively low solid solubility and hydrogen diffusion coefficient (e.g., lower than those of the main bodies 3111 and/or 3141 made of copper and/or titanium nitride), and thus protection layers made therefrom are effective in preventing contaminants (e.g., hydrogen) from passing through the conductive portion and entering into the channel 312 that is made of a metal oxide. Since the metal oxide channel 312 is well protected from the contaminants, performance and reliability of the metal oxide channel 312 are enhanced.

In accordance with some embodiments of the present disclosure, a method for manufacturing a transistor includes: forming a channel; forming a gate dielectric; forming a gate electrode spaced apart from the channel through the gate dielectric; and forming two contact structures that are spaced apart from each other and that are connected to the channel, at least one of the gate electrode and the two contact structures including a main body, and a protection layer that includes a transition metal which is one of elements of groups 3 to 12 in periods 5 to 7, elements of lanthanide series, and elements of actinide series.

In accordance with some embodiments of the present disclosure, the transition metal of the protection layer has a solid solubility lower than a solid solubility of a material of the main body.

In accordance with some embodiments of the present disclosure, the transition metal of the protection layer has a hydrogen diffusion coefficient lower than a hydrogen diffusion coefficient of a material of the main body.

In accordance with some embodiments of the present disclosure, the transition metal is one of ruthenium, rhodium, palladium, iridium, and combinations thereof.

In accordance with some embodiments of the present disclosure, the main body includes titanium nitride.

In accordance with some embodiments of the present disclosure, the protection layer has a portion disposed between the channel and the main body.

In accordance with some embodiments of the present disclosure, the protection layer has a portion disposed on the main body opposite to the channel.

In accordance with some embodiments of the present disclosure, the protection layer has a portion disposed on a sidewall of the main body.

In accordance with some embodiments of the present disclosure, an interconnect structure includes a transistor and a capacitor. The transistor includes a channel, a gate dielectric disposed on the channel, a gate electrode spaced apart from the channel through the gate dielectric, and two contact structures connected to the channel and spaced apart from each other. At least one of the two contact structures and the gate electrode including a main body, and a protection layer that includes a transition metal which is one of elements of groups 3 to 12 in periods 5 to 7, elements of lanthanide series, and elements of actinide series. The capacitor includes a first electrode connected to one of the two contact structures of the transistor, a second electrode, and a dielectric interposed between the first electrode and the second electrode.

In accordance with some embodiments of the present disclosure, the main body and the protection layer are made of different materials.

In accordance with some embodiments of the present disclosure, the protection layer has a solid solubility lower than a solid solubility of the main body, and a hydrogen diffusion coefficient lower than a hydrogen diffusion coefficient of the main body.

In accordance with some embodiments of the present disclosure, each of the two contact structures includes the main body and the protection layer. The first electrode includes a main body and a protection layer. The main body and the protection layer of the first electrode are made of materials that are respectively same as materials of the main body and the protection layer of each of the two contact structures.

In accordance with some embodiments of the present disclosure, the channel is made of a metal oxide.

In accordance with some embodiments of the present disclosure, the metal oxide is one of indium gallium zinc oxide, indium oxide, gallium oxide, zinc oxide, tin oxide, copper oxide, and combinations thereof.

In accordance with some embodiments of the present disclosure, a semiconductor includes a base structure having a conductive feature therein, a transistor disposed above the base structure, and a capacitor disposed on the transistor. The transistor includes a gate electrode, a gate dielectric, a channel spaced apart from the gate electrode through the gate dielectric, and two contact structures connected to the channel and spaced apart from each other. Each of the two contact structures includes a main body, and a protection layer that includes a transition metal which is one of elements of groups 3 to 12 in periods 5 to 7, elements of lanthanide series, and elements of actinide series. The capacitor includes a first electrode connected to one of the two contact structures of the transistor, a second electrode, and a dielectric interposed between the first electrode and the second electrode.

In accordance with some embodiments of the present disclosure, the transition metal is one of ruthenium, rhodium, palladium, iridium, and combinations thereof.

In accordance with some embodiments of the present disclosure, the channel is made of a metal oxide, the main body is made of titanium nitride, and the protection layer is made of ruthenium.

In accordance with some embodiments of the present disclosure, the channel has an upper surface and a lower surface opposite to each other. The gate dielectric is disposed on the lower surface of the channel. The gate electrode is disposed on the gate dielectric opposite to the channel. Each of the two contact structures includes an upper part disposed on the upper surface of the channel. The semiconductor structure further includes an interconnecting routing that interconnects the second electrode with the conductive feature.

In accordance with some embodiments of the present disclosure, each of the two contact structures further includes a lower part extending from the upper part through the channel and the gate dielectric to terminate at a lower end. The lower end is spaced apart from the gate electrode.

In accordance with some embodiments of the present disclosure, each of the two contact structures has an upper end distal from the channel. The upper ends of the two contact structures are at different height levels.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a transistor, comprising:
forming a channel;
forming a gate dielectric;
forming a gate electrode spaced apart from the channel through the gate dielectric; and
forming two contact structures that are spaced apart from each other and that are connected to the channel,
at least one of the gate electrode and the two contact structures including a main body, and a protection layer that includes a transition metal which is one of elements of groups 3 to 12 in periods 5 to 7, elements of lanthanide series, and elements of actinide series.

2. The method according to claim 1, wherein the transition metal of the protection layer has a solid solubility lower than a solid solubility of a material of the main body.

3. The method according to claim 1, wherein the transition metal of the protection layer has a hydrogen diffusion coefficient lower than a hydrogen diffusion coefficient of a material of the main body.

4. The method according to claim 1, wherein the transition metal is one of ruthenium, rhodium, palladium, iridium, and combinations thereof.

5. The method according to claim 4, wherein the main body includes titanium nitride.

6. The method according to claim 1, wherein the protection layer has a portion disposed between the channel and the main body.

7. The method according to claim 1, wherein the protection layer has a portion disposed on the main body opposite to the channel.

8. The method according to claim 1, wherein the protection layer has a portion disposed on a sidewall of the main body.

9. An interconnect structure, comprising:
a transistor including:
a channel;
a gate dielectric disposed on the channel;
a gate electrode spaced apart from the channel through the gate dielectric; and
two contact structures connected to the channel and spaced apart from each other, at least one of the two contact structures and the gate electrode including a main body, and a protection layer that includes a transition metal which is one of elements of groups 3 to 12 in periods 5 to 7, elements of lanthanide series, and elements of actinide series; and
a capacitor including:
a first electrode connected to one of the two contact structures of the transistor;
a second electrode; and
a dielectric interposed between the first electrode and the second electrode.

10. The interconnect structure according to claim 9, wherein the main body and the protection layer are made of different materials.

11. The interconnect structure according to claim 10, wherein the protection layer has a solid solubility lower than a solid solubility of the main body, and a hydrogen diffusion coefficient lower than a hydrogen diffusion coefficient of the main body.

12. The interconnect structure according to claim 11, wherein
each of the two contact structures includes the main body and the protection layer,
the first electrode includes a main body and a protection layer, and
the main body and the protection layer of the first electrode are made of materials that are respectively same as materials of the main body and the protection layer of each of the two contact structures.

13. The interconnect structure according to claim 9, wherein the channel is made of a metal oxide.

14. The interconnect structure according to claim 13, wherein the metal oxide is one of indium gallium zinc oxide, indium oxide, gallium oxide, zinc oxide, tin oxide, copper oxide, and combinations thereof.

15. A semiconductor structure, comprising:
a base structure having a conductive feature therein;
a transistor disposed above the base structure, and including:
a gate electrode;
a gate dielectric;
a channel spaced apart from the gate electrode through the gate dielectric; and
two contact structures connected to the channel and spaced apart from each other, each of the two contact structures including a main body, and a protection layer that includes a transition metal which is one of elements of groups 3 to 12 in periods 5 to 7, elements of lanthanide series, and elements of actinide series; and
a capacitor disposed on the transistor, and including:
a first electrode connected to one of the two contact structures of the transistor;
a second electrode; and
a dielectric interposed between the first electrode and the second electrode.

16. The semiconductor structure according to claim 15, wherein the transition metal is one of ruthenium, rhodium, palladium, iridium, and combinations thereof.

17. The semiconductor structure according to claim 15, wherein the channel is made of a metal oxide, the main body is made of titanium nitride, and the protection layer is made of ruthenium.

18. The semiconductor structure according to claim 15, wherein
the channel has an upper surface and a lower surface opposite to each other,
the gate dielectric is disposed on the lower surface of the channel,
the gate electrode is disposed on the gate dielectric opposite to the channel,
each of the two contact structures includes an upper part disposed on the upper surface of the channel, and
the semiconductor structure further comprises an interconnecting routing that interconnects the second electrode with the conductive feature.

19. The semiconductor structure according to claim 18, wherein each of the two contact structures further includes a lower part extending from the upper part through the channel and the gate dielectric to terminate at a lower end, the lower end being spaced apart from the gate electrode.

20. The semiconductor structure according to claim 15, wherein each of the two contact structures has an upper end distal from the channel, the upper ends of the two contact structures being at different height levels.
